(19) United States
(12) Patent Application Publication
(10) Pub. No.: US 2024/0310402 A1
(43) Pub. Date: Sep. 19, 2024

(54) DEVICE FOR THE CONTACTLESS DETECTION OF MOVEMENTS

(71) Applicant: Schaeffler Technologies AG & Co. KG, Herzogenaurach (DE)

(72) Inventors: Christian Mock, Schweinfurt (DE); Radoslav Rábik, Bytca (SK)

(73) Assignee: Schaeffler Technologies AG & Co. KG, Herzogenaurach (DE)

(21) Appl. No.: 18/576,424

(22) PCT Filed: Jun. 1, 2022
(86) PCT No.: PCT/DE2022/100409

§ 371 Date: Jan. 4, 2024

(30) Foreign Application Priority Data
Jul. 14, 2021 (DE) 10 2021 118 230.1

(51) Int. Cl. G01P 3/487; G01N 27/72; G01P 3/50; G01R 33/09; H01F 13/00

(52) U.S. Cl. CPC G01P 3/487; G01N 27/72; G01P 3/50; G01R 33/091; H01F 13/003

(57) ABSTRACT

A device for detecting rotational or linear movements includes a transmitter with sections, and a magnetoresistive sensor. The sections are alternatingly inversely magnetized along a trajectory extending in a first spatial direction. The sections includes respective magnetic poles that oppose each other in a second spatial direction, orthogonal to the first spatial direction, and an extent in a third spatial direction orthogonal to the first spatial direction and to the second spatial direction. The sections are magnetized over a length in the third spatial direction that is less than the extent. The magnetoresistive sensor is spaced from the transmitter by a gap in the second spatial direction, and the magnetoresistive sensor is stationary. The spatial directions may be directions in a cylindrical coordinate system or a cartesian coordinate system.

### CROSS-REFERENCE TO RELATED APPLICATIONS

This application is the United States National Phase of PCT Appln. No. PCT/DE2022/100409 filed Jun. 1, 2022, which claims priority to German Application No. DE102021118230.1 filed Jul. 14, 2021, the entire disclosures of which are incorporated by reference herein.

### TECHNICAL FIELD

The present disclosure relates to a device for contactlessly detecting rotational or linear movements, having a stationary magnetoresistive sensor and a transmitter. The transmitter has sections which are alternatingly inversely magnetized along a trajectory extending in a first spatial direction, and the magnetic poles of said sections opposing each other in a second spatial direction orthogonal to the first spatial direction. The sensor is spaced from the transmitter by a gap in the second spatial direction, and the sections of the transmitter have an extent in a third spatial direction orthogonal to the first and second spatial directions.

### BACKGROUND

Such devices are known from the prior art and are used, for example, on rolling bearings or vehicle wheels to detect rotational movements. This creates a magnetic field between the alternatingly magnetized sections, which magnetic field has field components in all spatial directions. On movement of the alternatingly magnetized sections along the sensor, the sensor detects sinusoidal amplitudes of all three field components. The movement is determined based on the magnetic field components detected by the sensor in the first spatial direction. The conflict then arises that the dimensions of the transmitter, in particular in the third spatial direction, may be predetermined by the fact that it fulfills other functions in addition to its function as a transmitter. In rolling bearings, for example, elastomers are used for sealing, which through magnetization are also intended as transmitters. The geometric requirements in particular of these components thus result from the further function and also from the property as a transmitter. Depending on the application, the positioning of the sensor also cannot be freely selected due to limited installation space.

The positioning of the sensor relative to the extent of the transmitter in the third spatial direction is important in that, in particular in the marginal region of this extent, magnetic field components are present in the third spatial direction—the “transverse field”-which can disrupt detection of the magnetic field components in the first spatial direction. Where the aforementioned geometric requirements resulting from the further function lead to unfavorable positioning of the sensor relative to the extent of the transmitter and this therefore detects a strong transverse field, reliable detection of the rotational movement is disadvantageously not possible.

DE 10 2007 023 385 A1 discloses a previously described device in which the sensor can be arranged perpendicularly or parallel to a plane in the first and third spatial directions or in any angular position therebetween.

### SUMMARY

The present disclosure proposes a device for contactlessly detecting rotational or linear movements, in which movement can be reliably detected.

A device according to the disclosure provides that the sections of the transmitter are magnetized over a length in the third spatial direction that is shorter than their extent in the third spatial direction. In this way, the geometry of the transmitter can be determined by other geometric requirements, such as a sealing function, while the magnetized length can be adapted to the sensor position in order to position the sensor favorably in the resulting magnetic field. The favorable factor here may be understood to be that the sensor sees low amplitudes of magnetic field components in the third spatial direction. Decoupling of the individual geometric requirements of the transmitter thus occurs. The magnetized length can be selected as desired and can therefore be adapted to any installation situation of the transmitter and the sensor.

The first spatial direction may be a circumferential direction, the second spatial direction may be an axial direction and the third spatial direction may be a radial direction of a cylindrical coordinate system. Such a device is suitable for detecting rotational movements.

Alternatively, the first spatial direction may be an x-direction, the second spatial direction may be a z-direction and the third spatial direction may be a y-direction of a Cartesian coordinate system. Such a device is suitable for detecting linear movement.

In an example embodiment, the transmitter is a component of a rolling bearing. The transmitter may be a component which already fulfills another function in the rolling bearing and to which the function of a transmitter is assigned, in addition to the other function, by magnetization. In one configuration of such an embodiment, the transmitter is a seal of the rolling bearing. The geometry of such a seal is largely determined by its sealing function, and decouples the magnetized geometry from the external geometry of the transmitter as described above.

In a further configuration of the aforementioned embodiment, the transmitter is arranged on a surface of the rolling bearing, surface normal of which points in an axial direction. The first spatial direction may be a circumferential direction, the second spatial direction may be an axial direction and the third spatial direction may be a radial direction of a cylindrical coordinate system. The sensor can then be arranged conveniently in the axial direction next to the rolling bearing. Alternatively, the transmitter can be arranged on a surface of the rolling bearing, the surface normal of which points in a radial direction. The first spatial direction may be a circumferential direction, the second spatial direction may be a radial direction and the third spatial direction may be an axial direction of a cylindrical coordinate system. The sensor can then be arranged radially on the outside of the rolling bearing.

The transmitter may be made from an elastomer. For example, the transmitter is a seal of a rolling bearing and is made from an elastomer. Elastomers can be used for complex geometries and can be magnetized in a simple manner. They are also suitable for forming seals.

In one embodiment, the magnetoresistive region of the sensor is arranged in the third spatial direction centrally or immediately adjacent to the center of the magnetized length of the sections of the transmitter. The magnetoresistive region of the sensor is the region in the third spatial direction in which the magnetic field components are detected by the sensor. For the purposes of the disclosure, the arrangement is to be understood to be central if there are slight deviations from an exactly central position. For example, the position is to be understood as central even if it lies 5%, 10% or 15% of the magnetized length away from the exact center. In the geometric center or immediately adjacent thereto, a minimum of the amplitude of the magnetic field components is usually to be expected in the third spatial direction, for example, if the transmitter is designed to be uniform in the third spatial direction. In devices in which the first spatial direction is a circumferential direction of a cylindrical coordinate system, this minimum may be be immediately adjacent to the center. There is then minimal interference with detection of the magnetic field components in the first spatial direction by the sensor. Central positioning of the sensor or positioning thereof immediately adjacent to the center can be achieved with a specified geometry of the transmitter in the third spatial direction and a specified position of the sensor by selecting the magnetized length and positioning thereof.

The transmitter can optionally be magnetized in the third spatial direction from one of its edges to a point along its extent. The magnetized length can also be spaced on both sides from the edges of the extent.

Another aspect of the disclosure relates to a rolling bearing having a device as described above. Such a device also has the advantages mentioned with regard to the device as described above.

Another aspect of the disclosure relates to a method for producing such a device. Such a method provides that a tool provided for magnetizing the transmitter extends over the length to be magnetized, which is shorter than the extent of the sections of the transmitter in the third spatial direction. In this way, the length to be magnetized is determined and can be produced reliably.

A fundamental manufacturing-related advantage of the invention consists moreover in the fact that a large number of sensor positions can be implemented with one and the same geometry of the transmitter. There is therefore no need to adapt the tool to produce the transmitter.

### BRIEF DESCRIPTION OF THE DRAWINGS

Further details of the disclosure are illustrated in greater detail below together with the description of exemplary embodiments made with reference to the figures, in which

FIG. 1 shows a plan view of a first embodiment of a device according to the disclosure,

FIG. 2 shows a perspective view of a second embodiment of a device according to the disclosure,

FIG. 3a shows an exemplary diagrammatic representation of the maximum amplitude of the magnetic field component in the first spatial direction,

FIG. 3b shows an exemplary diagrammatic representation of the maximum amplitude of the magnetic field component in the second spatial direction,

FIG. 3c shows an exemplary diagrammatic representation of the maximum amplitude of the magnetic field component in the third spatial direction,

FIG. 4a shows a sectional representation of a section of the transmitter in an embodiment according to the prior art,

FIG. 4b shows a sectional representation of a section of the transmitter in a first embodiment according to the disclosure,

FIG. 4c shows a sectional representation of a section of the transmitter in a second embodiment according to the disclosure,

FIG. 4d shows a sectional representation of a section of the transmitter in a third embodiment according to the disclosure,

FIG. 5 shows an exemplary diagrammatic representation of the maximum amplitude of the magnetic field component in the third spatial direction in various embodiments according to the prior art and according to the disclosure,

FIG. 6a shows a perspective view of a component of a rolling bearing according to the prior art,

FIG. 6b shows a perspective view of a component of a rolling bearing according to the disclosure in a first embodiment, and

FIG. 6c shows a perspective view of a component of a rolling bearing according to the disclosure in a second embodiment.

### DETAILED DESCRIPTION

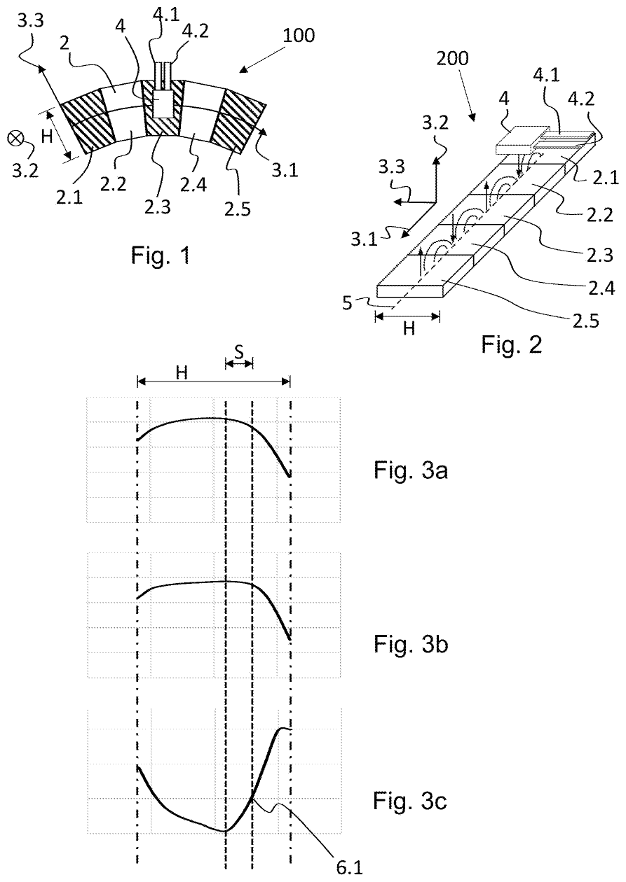

FIG. 1 shows a device 100 according to the disclosure, having a transmitter 2, which has alternatingly oppositely magnetized sections 2.1, 2.2, 2.3, 2.4, 2.5 along a trajectory in a first spatial direction 3.1, which here is a circumferential direction. The sections 2.1, 2.3, 2.5 are shown hatched, which indicates a first polarity. In sections 2.1, 2.3, 2.5 with the first polarity there is a north pole in the second spatial direction 3.2, which here is an axial direction and extends into the plane of the drawing, on the side facing the viewer and a south pole on the side facing away. The sections 2.2, 2.4 located therebetween have, according to a second polarity, a north pole on the side facing away from the viewer and a south pole on the side facing the viewer. A radial direction is provided as the third spatial direction 3.3. The transmitter 2 or its sections 2.1, 2.2, 2.3, 2.4, 2.5 have an extent H in this third spatial direction 3.3.

FIG. 1 also shows a sensor 4 which has terminal contacts 4.1, 4.2 arranged thereon. The sensor 4 is arranged in the second spatial direction 3.2 above the transmitter 2 and is spaced therefrom by an air gap. The sensor 4 is designed to detect the magnetic field components between the sections 2.1, 2.2, 2.3, 2.4, 2.5 in the first spatial direction 3.1.

FIG. 2 shows a further embodiment of the device 200 according to the disclosure having a transmitter 2 with sections 2.1, 2.2, 2.3, 2.4, 2.5 and a sensor 4. The sections 2.1, 2.2, 2.3, 2.4, 2.5 are arranged one behind the other in the first spatial direction 3.1, which here is an axial direction. The second spatial direction 3.2 and the third spatial direction 3.3 are perpendicular to the first spatial direction 3.1. FIG. 2 also shows amplitudes of magnetic field components in the first spatial direction 3.1 and the second spatial direction 3.2 at sections 2.1, 2.2, 2.3, 2.4, 2.5 along an axial center line 5, which in turn result from the alternatingly opposite magnetization.

Magnetization according to the disclosure for the devices 100 and 200 is shown in the subsequent FIGS. 3a to 6c. FIGS. 3a, 3b, 3c show the courses of the amplitudes of magnetic field components when scanning in the first spatial direction 3.1 over the extent H of the sections 2.1, 2.2, 2.3, 2.4, 2.5 in the third spatial direction 3.3 in the case of magnetization known from the prior art over the entire extent H. The amplitude of the magnetic field component in the first spatial direction 3.1 is shown in FIG. 3a. This is largely constant at a sufficient distance from the edges of the extent H and falls off towards the edges. The amplitude of the magnetic field component behaves in approximately the same way in the second spatial direction 3.2, which is shown in FIG. 3b. The amplitude of the magnetic field component in the third spatial direction 3.3, which is shown in FIG. 3c, behaves opposingly. It is particularly pronounced in regions near the edges of the extent H and has a minimum approximately in the center. The magnetic field component in the third spatial direction 3.3 may interfere with the desired detection of the magnetic field component in the first spatial direction 3.1. A sensor 4 may detect the magnetic field components in a region with high amplitude in the first spatial direction 3.1 and low amplitude in the third spatial direction 3.3 in order to ensure reliable detection.

Furthermore, a projection of a magnetoresistive region S of the sensor 4 is shown in FIGS. 3a, 3b, 3c. This corresponds to the reading range of the sensor 4 with a predetermined positioning of the sensor 4. As can be seen from FIG. 3c, the magnetoresistive region S lies in such a way relative to the extent H that it is exposed to a comparatively high amplitude of the magnetic field component in the third spatial direction 3.3, at least at the point 6.1.

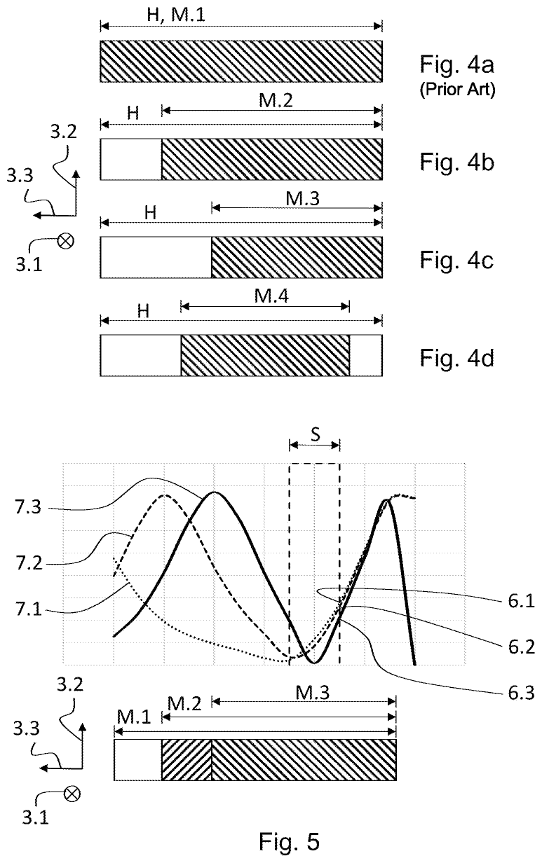

FIGS. 4a, 4b, 4c, 4d show one of the sections 2.1, 2.2, 2.3, 2.4, 2.5 in sectional representation, wherein the first spatial direction 3.1 here is perpendicular to the plane of the drawing. The magnetized length M.1, M.2, M.3, M.4 of the sections 2.1. 2.2. 2.3, 2.4, 2.5 in the third spatial direction 3.3 is shown by hatching. In FIG. 4a, which corresponds to the prior art, the sections 2.1, 2.2, 2.3, 2.4, 2.5 are magnetized over the entire extent H thereof. In FIGS. 4b and 4c the magnetized length M.2, M.3 is shorter, according to the disclosure, than the extent H, namely it ends on one side before the end of the extent H. In FIG. 4d, according to the disclosure, the magnetized length M.4 is also shorter than the extent H, but ends on both sides before the respective end of the extent H.

FIG. 5 compares the embodiments of FIGS. 4a, 4b, 4c in a diagram according to FIG. 3c, which shows the amplitude of the magnetic field component in the third spatial direction 3.3 over the extent H. A first graph 7.1 here corresponds to the magnetic field component in the third spatial direction 3.3 in the case of a magnetized length M. 1 according to FIG. 4a, a second graph 7.2 corresponds to the magnetic field component in the third spatial direction 3.3 in the case of a magnetized length M.2 according to FIG. 4b and a third graph 7.3 corresponds to the magnetic field component in the third spatial direction 3.3 in the case of a magnetized length M.3 according to FIG. 4c. FIGS. 4a, 4b, 4c are shown below the diagram, with different hatching superimposed.

A projection of the magnetoresistive region S of the sensor is in turn shown in FIG. 5. As can be seen in the comparison of the points 6.1, 6.2 and 6.3, the respective maximum amplitude of the magnetic field component in the third spatial direction 3.3 is lowest in an embodiment according to FIG. 4c (point 6.3). In the embodiment according to FIG. 4b (point 6.2) too, the maximum amplitude present is lower than in the embodiment according to the prior art (point 6.1).

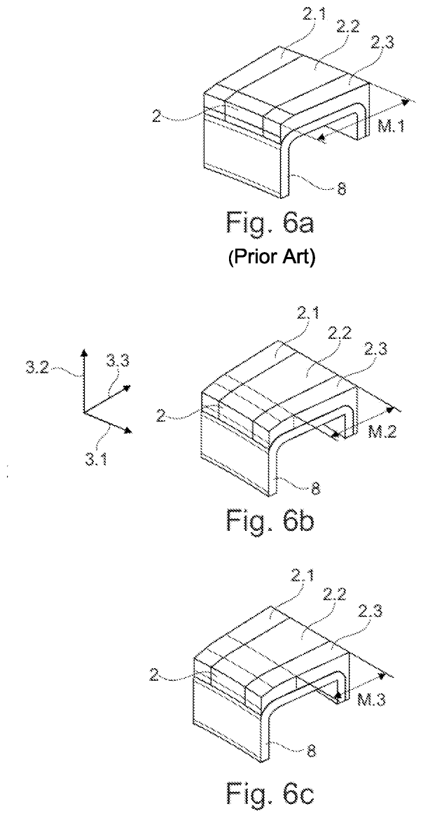

FIGS. 6a, 6b, 6c each show a transmitter 2 according to the disclosure with sections 2.1, 2.2, 2.3, wherein the transmitter 2 here is a seal on a component 8 of a rolling bearing. The seal is, for example, formed from a magnetizable elastomer. In FIG. 6a, the transmitter 2 is magnetized over its entire extent H, corresponding to FIG. 4a and thus according to the prior art. In FIG. 6b the transmitter 2 is magnetized over a length M.2 corresponding to FIG. 4b, and in FIG. 6c it is magnetized over a length M.3 corresponding to FIG. 4c.

### REFERENCE NUMERALS

2 Transmitter
2.1 First section of the transmitter
2.2 Second section of the transmitter
2.3 Third section of the transmitter
2.4 Fourth section of the transmitter
2.5 Fifth section of the transmitter
3.1 First spatial direction
3.2 Second spatial direction
3.3 Third spatial direction
4 Sensor
4.1 First terminal contact
4.2 Second terminal contact
5 Axial center line
6.1 First point
6.2 Second point
6.3 Third point
7.1 First graph
7.2 Second graph
7.3 Third graph
8 Component of a rolling bearing
100 Device
200 Device
H Extent of a section of the transmitter in the third spatial direction
M.1 First magnetized length
M.2 Second magnetized length
M.3 Third magnetized length
M.4 Fourth magnetized length
S Magnetoresistive region of the sensor

1. A device for contactlessly detecting rotational or linear movements, having a stationary magnetoresistive sensor and a transmitter, wherein the transmitter has sections which are alternatingly inversely magnetized along a trajectory extending in a first spatial direction, the magnetic poles of said sections opposing each other in a second spatial direction orthogonal to the first spatial direction, wherein the sensor is spaced from the transmitter by a gap in the second spatial direction, and the sections of the transmitter have an extent (H) in a third spatial direction orthogonal to the first and second spatial directions,
wherein the sections of the transmitter are magnetized over a (M.2, M.3, M.4) length in the third spatial direction that is shorter than their extent (H) in the third spatial direction.

2. The device according to claim 1,
wherein the first spatial direction is a circumferential direction, the second spatial direction is an axial direction and the third spatial direction is a radial direction of a cylindrical coordinate system.

3. The device according to claim 1,
wherein the first spatial direction is an x-direction, the second spatial direction is a z-direction and the third spatial direction is a y-direction of a Cartesian coordinate system.

4. The device according to claim 1,
wherein the transmitter is a component of a rolling bearing.

5. The device according to claim 4,
wherein the transmitter is a seal.

6. The device according to claim 4,
wherein the transmitter is arranged on a surface of the rolling bearing, the surface normal of which points in an axial direction.

7. The device according to claim 1,
wherein the transmitter is made from an elastomer.

8. The device according to claim 1,
wherein the magnetoresistive region (S) of the sensor is arranged in the third spatial direction centrally or immediately adjacent to the center of the magnetized length (M.2, M.3, M.4) of the sections of the transmitter.

9. A rolling bearing having a device according to claim 1.

10. A method for producing a device according to claim 1,
wherein a tool provided for magnetizing the transmitter extends over the length (M.2, M.3, M.4) to be magnetized, which is shorter than the extent (H) of the sections of the transmitter in the third spatial direction.

11. A device for detecting rotational or linear movements, comprising:
a transmitter comprising sections, the sections:
being alternatingly inversely magnetized along a trajectory extending in a first spatial direction;
comprising respective magnetic poles that oppose each other in a second spatial direction, orthogonal to the first spatial direction; and
comprising an extent in a third spatial direction orthogonal to the first spatial direction and to the second spatial direction, the sections being magnetized over a length in the third spatial direction that is less than the extent; and
a magnetoresistive sensor spaced from the transmitter by a gap in the second spatial direction, the magnetoresistive sensor being stationary.

12. The device of claim 11, wherein:
the first spatial direction is a circumferential direction of a cylindrical coordinate system;
the second spatial direction is an axial direction of the cylindrical coordinate system; and
the third spatial direction is a radial direction of the cylindrical coordinate system.

13. The device of claim 11, wherein:
the first spatial direction is an x-direction of a cartesian coordinate system;
the second spatial direction is a z-direction of the cartesian coordinate system; and
the third spatial direction is a y-direction of the cartesian coordinate system.

14. The device of claim 11 wherein the transmitter is a component of a rolling bearing.

15. The device of claim 14 wherein the transmitter is a seal of the rolling bearing.

16. The device of claim 11 wherein the transmitter is arranged on a surface of a rolling bearing, the surface comprising a surface normal pointing in an axial direction of the rolling bearing.

17. The device of claim 11 wherein the transmitter is made from an elastomer.

18. The device of claim 11 wherein the magnetoresistive sensor comprises a magnetoresistive region arranged in the third spatial direction central to or immediately adjacent to a center of the length.
